(19) United States
(12) Patent Application Publication
(10) Pub. No.: US 2011/0084579 A1
(43) Pub. Date: Apr. 14, 2011

(54) HOUSING OF ELECTRONIC DEVICE AND MANUFACTURING METHORD THEREOF

(75) Inventor: CHUN-YUAN CHANG, Tu-Cheng (TW)

(73) Assignee: HON HAI PRECISION INDUSTRY CO., LTD., Tu-Cheng (TW)

(21) Appl. No.: 12/780,949

(22) Filed: May 17, 2010

(30) Foreign Application Priority Data
Oct. 13, 2009 (CN) 200910308219.7

(51) Int. Cl. H05K 5/03; H05K 5/04; B21D 11/10; B29C 45/14; B29C 45/72

(52) U.S. Cl. 312/223.1; 72/379.4; 264/145; 264/275; 264/447

(57) ABSTRACT

A housing includes a metal cover defining an opening and a patched member adhered to the cover to patch the opening. The patched member is formed by injecting resin into the opening of the cover in an injection mold for in-mold-decoration. A film is attached to an outer surface of the patched member.

### BACKGROUND

1. Technical Field

The disclosure relates to a housing of an electronic device, and a method for manufacturing the housing.

2. Description of Related Art

A housing of an electronic device, such as a notebook computer or a mobile phone, is mostly made of metal. The metal housing is patched with a plastic member for uninterrupted signal transmission. However, the color and luster of the patched member generally have sharp contrasts relative to the metal. Therefore, for aesthetical value a plastic coating is needed to cover these contrasts.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a schematic view of an embodiment of a housing of an electronic device.

FIG. 2 is an inverted view of FIG. 1.

FIG. 3 is an exploded, isometric view of the housing of FIG. 2, the housing includes a cover and a patched member.

FIG. 4 is a cross-sectional view of the patched member of FIG. 3.

FIG. 5 is a flowchart of a first exemplary embodiment of a method for manufacturing the housing of FIG. 1.

FIG. 6 is a schematic and cross-sectional view of an injection mold used in the method of manufacturing a plastic article of FIG. 5.

FIG. 7 is a flowchart of a second embodiment of the method for manufacturing the housing of FIG. 1.

FIG. 8 is a cross-sectional view of a film covering the patched member of the housing of FIG. 1.

FIG. 9 is a schematic and cross-sectional view of an injection mold used in the method of manufacturing a plastic article of FIG. 7.

FIG. 10 is a cross-sectional view of another embodiment of a housing of an electronic device.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

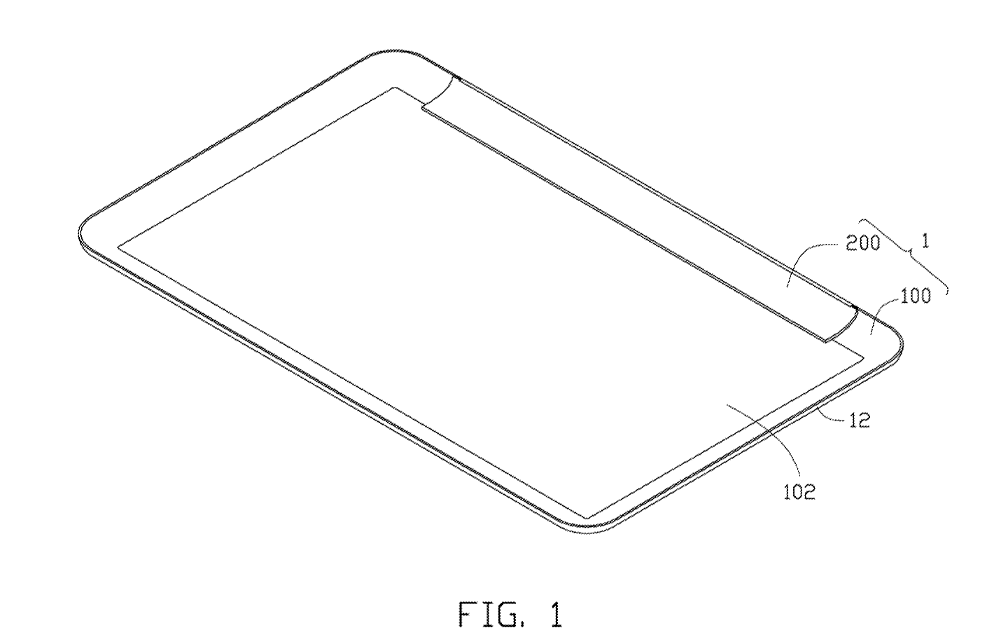

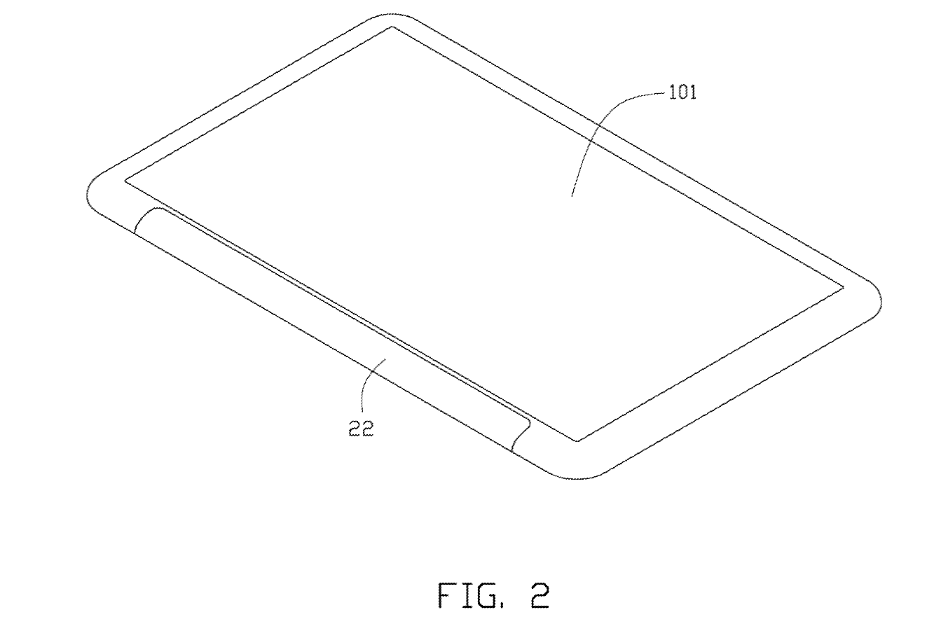

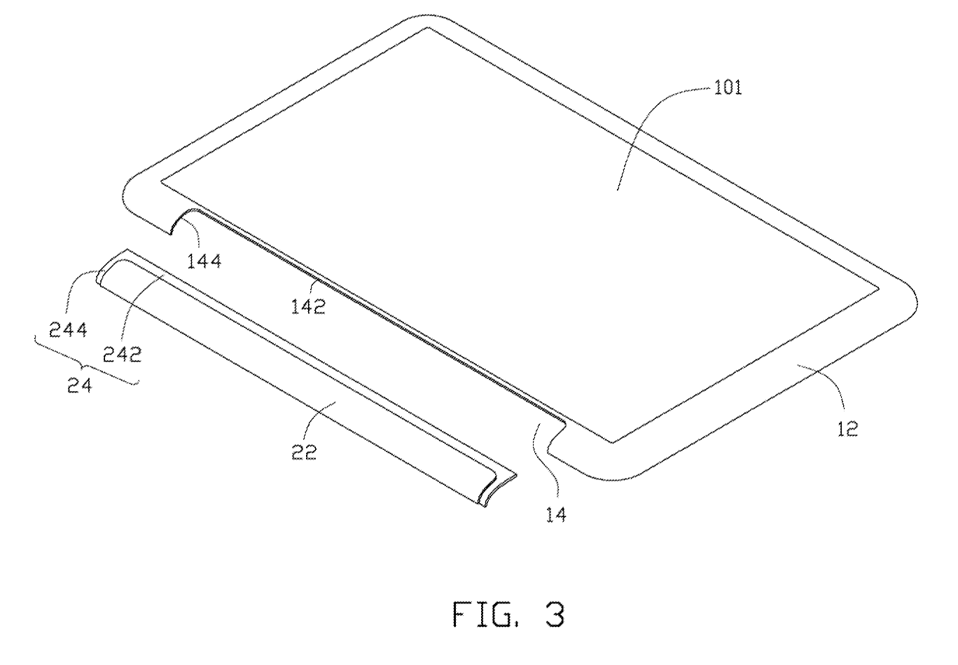

Referring to FIG. 1 to FIG. 3, an exemplary embodiment of a housing 1 may be used for portable electronic devices, such as mobile phones, or notebook computers. The housing 1 includes a cover 100 and a patched member 200.

The cover 100 is approximately rectangular and includes an outer surface 101 and an inner surface 102 opposite to the outer surface 101. A flange 12 extends towards a direction of the inner surface 102 from four edges of the housing 1. An arc-shaped corner is formed between every two adjacent sides of the flange 12. An opening 14 is defined in the cover 100, at one side thereof. In this embodiment, the opening 14 extends through an edge of the flange 12, thereby forming a straight edge 142 and two arc-shaped edges 144 bounding the opening 14.

The cover 100 can be made of a first material, in this embodiment the first material is metal, such as copper, iron, aluminum, titanium, or alloys that can include one or more of these metals. In one embodiment, aluminum alloy sheet metal is used. The thickness of the sheet metal ranges from about 0.2 millimeters (mm) to about 1.5 mm. In one embodiment, the thickness is about 0.8 mm.

The patched member 200 is made of a second material, such as resin or plastic, and is formed by injecting resin into the opening 14 of the cover 100 in an injection mold for in-mold-decoration. The patched member 200 includes a cover portion 22 that is matched with the opening 14 and an adhesive portion 24 around it that is connected to three sides of the cover portion 22. The adhesive portion 24 includes a straight section 242 and two arc-shaped sections 244. After molding, the straight section 242 of the adhesive portion 24 is attached to the straight edge 142 of the cover 100, and the two arc-shaped sections 244 of the adhesive portion 24 are attached to the two edges 144 of the cover 100, respectively. The surface of the cover portion 22 is substantially stepped relative to the adhesive portion 24 and level to an outer surface of the cover 100.

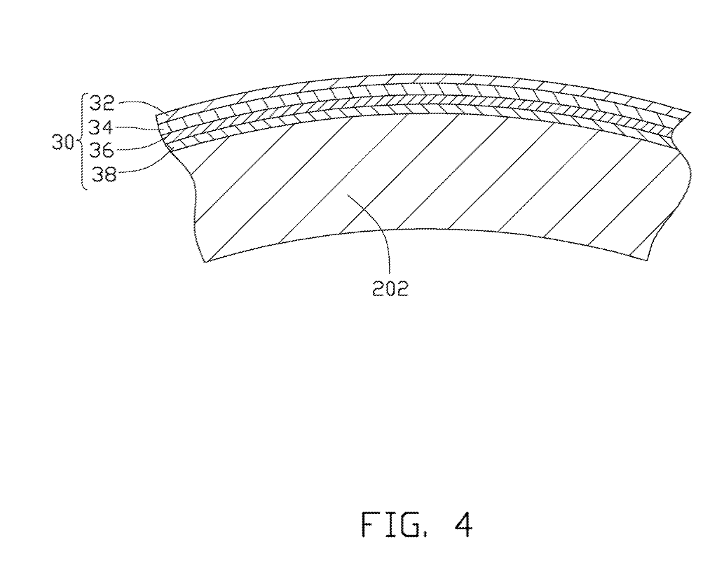

Referring to FIG. 4, the cover portion 22 of the patched member 200 includes a plastic article 202 and a film 30 covering the plastic article 202. The film 30 includes a base layer 32, a first attaching layer 34, a pattern layer 36, and a second attaching layer 38.

The base layer 32 functions as a scratch/abrasion-resistant layer for the pattern layer 36. The base layer 32 generally includes at least one of polycarbonate, polyethylene terephthalate, acrylic, oriented polypropylene, and polyvinyl chloride. The thickness of the base layer 32 can range from about 0.03 mm to about 0.125 mm.

The pattern layer 36 may be provided by printing ink on the base layer 32. A metal decorative layer can be provided as the pattern layer 36. The metal decorative layer may be aluminum, chromium, copper, nickel, indium, or tin, alone or combined, on the base layer 32 by either a vacuum evaporation or electroplating method.

The first attaching layer 34 is sandwiched between the pattern layer 36 and the base layer 32, for retaining the pattern layer 36 to be adhered to the base layer 32. The first and second attaching layers 34 and 38 may be made from at least one type of a plurality of resin materials including acrylic, nitrification fiber, polyamine formate, chlorination rubber, vinyl chloride-co-vinyl-acetic ester copolymer, polyamide, polyester, epoxy, polycarbonate, olefin, or acrylonitrile-butylene-styrene monomer resin. The second attaching layer 38 is generally provided by concave, screen, and offset printing, or spraying, dip-coating method, or a coating in reverse order method. The thickness of the second attaching layer 38 can range from about 0.0005 mm to about 0.05 mm.

The base layer 32 may be either transparent or translucent to reveal the patterns and/or colors of the pattern layer 36.

In an altered embodiment, the film 30 includes a base layer 32, a first attaching layer 34 and a pattern layer 36, but does not include a second attaching layer 38.

In another altered embodiment, the film 30 includes a base layer 32, a first attaching layer 34, but does not include a pattern layer 36, for highlighting the natural color of the resin of the plastic article 202 through the transparent or translucent base layer 32. It is noteworthy that in other embodiments, the base layer 32 may be made of a colored material, for adding color to the plastic article.

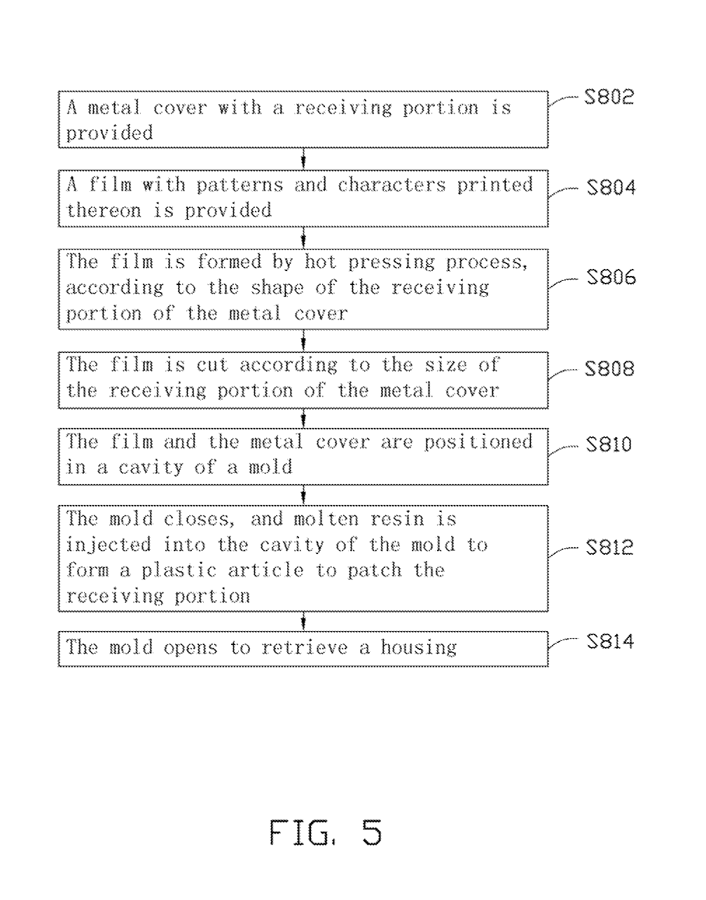

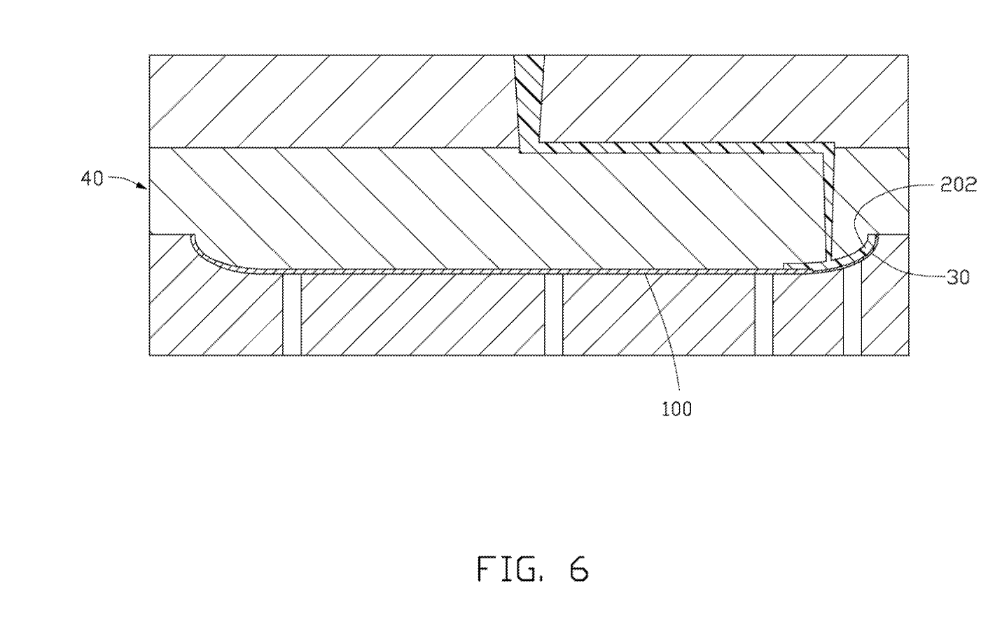

Referring to FIGS. 5 and 6, a first exemplary embodiment of a method to manufacture the housing 1, includes the following steps.

Step S802, a cover 100 defining an opening 14 is provided. In one embodiment, a stamping process with a punch die makes the cover 100.

Step S804, the film 30 with patterns and characters printed on the film 30 is provided.

Step S806, the film 30 is processed by hot pressing process, according to the shape of the opening 14 of the cover 100.

Step S808, the film 30 is cut according to the size of the opening 14 of the cover 100.

Step S810, the film 30 and the cover 100 are positioned in a cavity of a mold 40, so that the film 30 is located corresponding to the opening 14.

Step S812, the mold 40 is closed and molten resin is injected into the cavity of the mold 40 to form the plastic article 202, which is attached to the film 30.

Step S814, the mold 40 is opened to retrieve the housing 1. The film 30 covers an outer surface of the plastic article 202 to form the patched member 200. The patched member 200 patches the opening 14 of the cover 100.

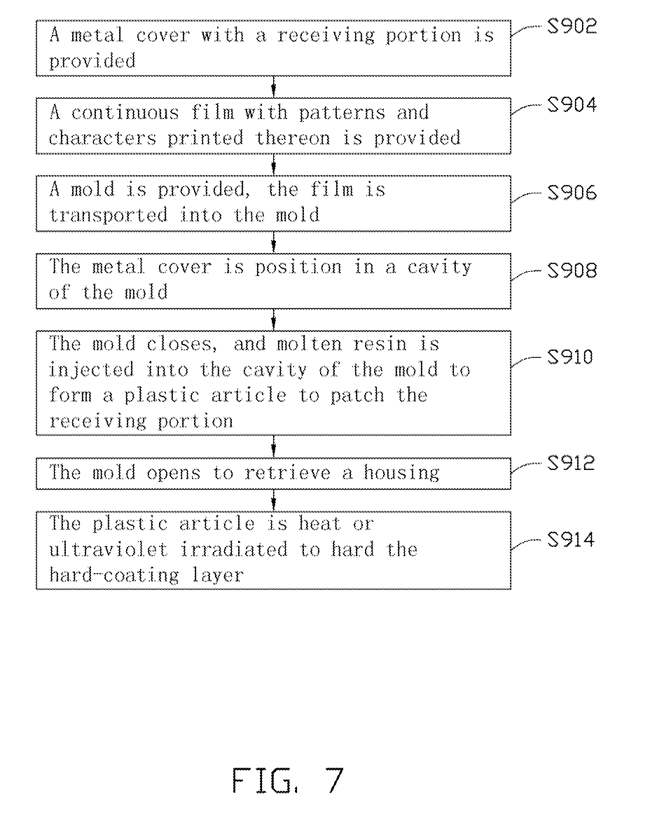

Referring to FIGS. 7-9, a second embodiment of the method for manufacturing a housing of an electronic device includes the following steps.

Step S902, a cover 100 defining an opening 14 is provided. In one embodiment, the cover 100 is made by stamping process with a punch die.

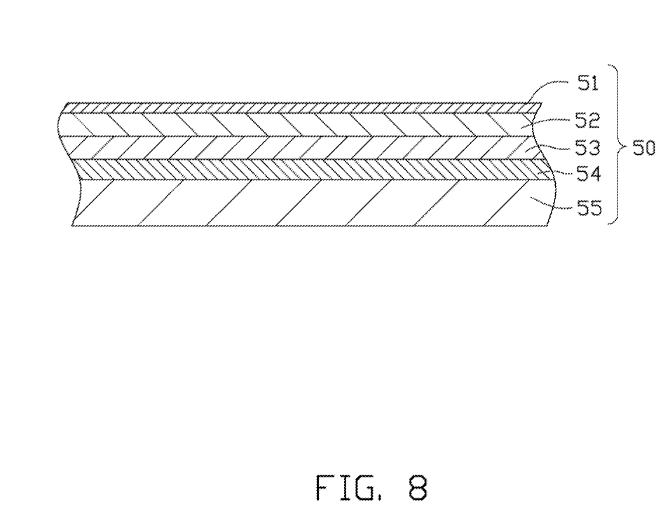

Step S904, a continuous film 50 with patterns and characters printed thereon is provided. The film 50 includes a continuous carrier layer 51, and a release layer 52, a hard-coating layer 53, a pattern layer 54 and an attaching layer 55 attached to the continuous carrier layer 52 in that order, shown in FIG. 8.

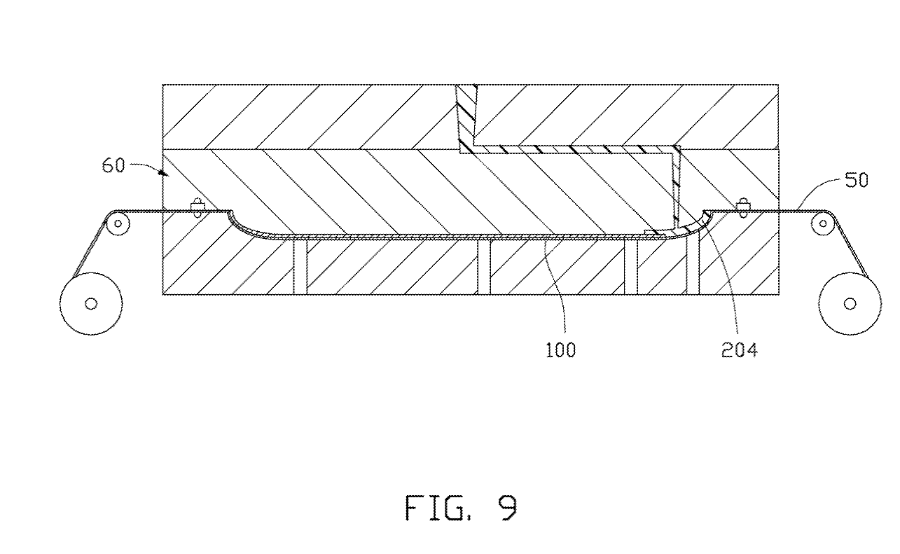

Step S906, a mold 60 is provided, which includes a male mold and a female mold. The film 50 is transported between the female and male molds of the mold 60, as shown in FIG. 9.

Step S908, a cover 100 is positioned in a cavity of the mold 60.

Step S910, the mold 60 is closed, and molten resin is injected into the cavity of the mold 60 to form the plastic article 204 attached to the film 50, to patch the opening 14.

Step S912, the mold 60 is opened to retrieve the housing. The hard-coating layer 53, the pattern layer 54, and the attaching layer 55 of the film 50 are attached to an outer surface of the plastic article 204. The carrier layer 51 and the release layer 52 of the film 50 are released from the plastic article 204. The patched member 200 patches the opening 14 of the cover 100.

Step S914, the plastic article 204 is heated or ultraviolet irradiated to hard the hard-coating layer 53.

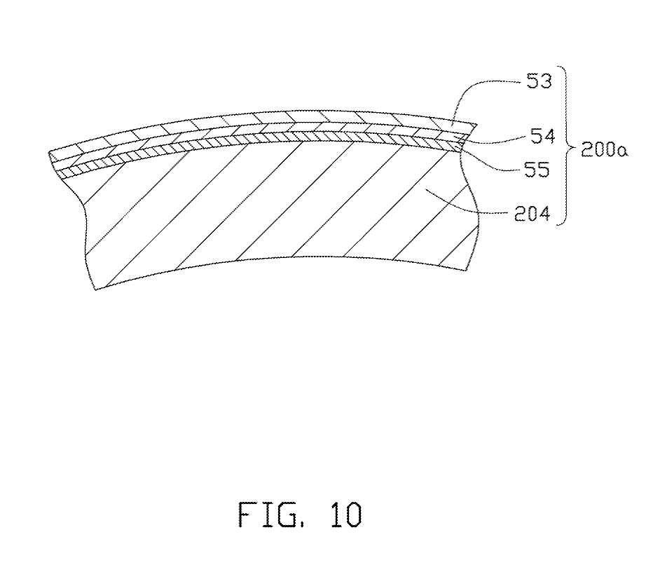

Referring to FIG. 10, a patched member 200a manufactured by the second embodiment of the method includes a plastic article 204, a hard-coating layer 53, a pattern layer 54, and an attaching layer 55. The hard-coating layer 53 functions as a scratch/abrasion-resistant layer for the pattern layer 54. The attaching layer 55 adheres the hard-coating layer 53 and the pattern layer 54 to the plastic article 204.

It is believed that the present embodiments and their advantages will be understood from the foregoing description, and it will be apparent that various changes may be made thereto without departing from the spirit and scope of the description or sacrificing all of its material advantages, the examples hereinbefore described merely being exemplary embodiments.

What is claimed is:

1. A housing for an electronic device, the housing comprising:
a cover made of a first material, the cover defining an opening; and
a patched member made of a second material, wherein the patched member is adhered to the cover to patch the opening;
wherein the patched member comprises a film attached to an outer surface of the patch member.

2. The housing of claim 1, wherein the first material comprises copper, iron, aluminum, titanium, singly or in combination.

3. The housing of claim 1, wherein the cover is made of aluminum alloy.

4. The housing of claim 1, wherein a flange extends towards an inner surface from edges of the cover.

5. The housing of claim 1, wherein the thickness of the cover ranges from about 0.8 millimeters to about 1.2 millimeters.

6. The housing of claim 1, wherein the patched member further comprises a plastic article formed by injecting resin into the opening of the cover in an injection mold for in-mold-decoration, the film is attached to an outer surface of the plastic article to form the patched member.

7. The housing of claim 1, wherein the opening extends through an edge of the cover.

8. The housing of claim 1, wherein the patched member comprises a cover portion mating with the opening and an adhesive portion around and connected to three sides of the cover portion.

9. The housing of claim 8, wherein the adhesive portion comprises a straight section and two arc-shaped sections, the opening is bounded by a straight edge and two arc-shaped edges, the straight section of the adhesive portion is attached to the straight edge of the cover, and the two arc-shaped sections of the adhesive portion are attached to the two arc-shaped edges of the cover, respectively.

10. The housing of claim 8, wherein the surface of the cover portion is stepped relative to the adhesive portion and level to an outer surface of the cover.

11. The housing of claim 10, wherein the film comprises a base layer, a first attaching layer, a pattern layer, and a second attaching layer, the second attaching layer adheres the film to the plastic article, the pattern layer is sandwiched between the first attaching layer and the second attaching layer.

12. The housing of claim 11, wherein the thickness of the base layer ranges from about 0.03 millimeters to about 0.125 millimeters.

13. The housing of claim 1, wherein the film comprises a base layer, a first attaching layer, and a pattern layer, the first attaching layer is sandwiched between the base layer and the pattern layer.

14. The housing of claim 1, wherein the film comprises a hard-coating layer, a pattern layer, and an attaching layer, the hard-coating layer functions as a scratch/abrasion-resistant layer for the pattern layer, the attaching layer adheres the hard-coating layer and the pattern layer to the patched member.

15. A method for manufacturing a housing of an electronic device, the method comprising:
providing a cover defining an opening;
providing a film;
processing the film by hot pressing process, according to the shape of the opening of the metal cover;
cutting the film according to the size of the opening of the cover;
positioning the film and the cover in a mold, with the film positioned corresponding to the opening of the cover;
closing the mold and injecting molten resin into the mold to form a plastic article to patch the opening; and
opening the mold to retrieve the housing.

16. The method of claim 13, wherein the cover is made of metal and formed by stamping process.

17. A method for manufacturing a housing of an electronic device, the method comprising:
providing a cover defining an opening;
providing a continuous film;
providing a mold;
transporting the film into the mold;
positioning the cover in the mold, with the film positioned at the opening of the cover;
closing the mold and injecting molten resin into the mold to form a plastic article to patch the opening; and
opening the mold to retrieve the housing.

18. The method of claim 17, wherein the film comprises a continuous carrier layer, and a release layer, a hard-coating layer, a pattern layer and an attaching layer attached to the continuous carrier layer in that order.

19. The method of claim 17, wherein after molding, the hard-coating layer, the pattern layer, and the attaching layer of the film are attached to an outer surface of the plastic article, the carrier layer and the release layer of the film are released from the plastic article.

20. The method of claim 19, further comprising:
heating or ultraviolet irradiating the plastic article to hard the hard-coating layer.
